(19) United States
(12) Patent Application Publication
(10) Pub. No.: US 2017/0006709 A1
(43) Pub. Date: Jan. 5, 2017

(54) PAD-TO-PAD EMBEDDED CAPACITANCE IN LIEU OF SIGNAL VIA TRANSITIONS IN PRINTED CIRCUIT BOARDS

(71) Applicant: International Business Machines Corporation, Armonk, NY (US)

(72) Inventors: Zhaoqing Chen, Poughkeepsie, NY (US); Matteo Cocchini, Long Island City, NY (US); Rohan Mandrekar, Sunnyvale, CA (US); Tingdong Zhou, Austin, TX (US)

(21) Appl. No.: 14/859,382

(22) Filed: Sep. 21, 2015

Related U.S. Application Data
(63) Continuation of application No. 14/755,551, filed on Jun. 30, 2015.

(51) Int. Cl. H05K 3/30

(52) U.S. Cl. CPC H05K 3/303

(57) ABSTRACT

In one embodiment, a method includes positioning a first signal pad in a first layer of a printed circuit board and positioning a second signal pad in a second layer of the printed circuit board. The second signal pad is positioned to form an embedded capacitance between the first signal pad and the second signal pad. The embedded capacitance between the first signal pad and the second signal pad is configured to carry a signal between the first layer and the second layer absent a signal via.

### DOMESTIC PRIORITY

This application is a continuation of U.S. patent application Ser. No. 14/755,551, filed Jun. 30, 2015, the disclosure of which is incorporated by reference herein in its entirety.

### BACKGROUND

Various embodiments of this disclosure relate to printed circuit boards (PCBs) and, more particularly, to pad-to-pad embedded capacitance in lieu of signal via transitions in printed circuit boards.

In a multi-layer PCB, signal vias are physical connections in the form of metal barrels. Signal vias allow traces, and thus signals carried by traces, to move from layer to layer of the PCB. However, via transitions are among the largest discontinuities in a PCB channel, hence damaging to the quality of the signals they transmit

If one of two layers connected by a signal via is an inner layer of the PCB, a portion of that signal via, referred to as a via stub, is not be included in the electrical path of the signal and can create additional reflections. Via stubs are commonly major sources of discontinuity in PCB layouts. Several techniques have been implemented to reduce the losses and resonances due to these discontinuities. A common such technique is stub backdrilling, which allows for the removal of the stub portion of the signal via.

### SUMMARY

In one embodiment of this disclosure, a method includes positioning a first signal pad in a first layer of a printed circuit board and positioning a second signal pad in a second layer of the printed circuit board. The second signal pad is positioned to form an embedded capacitance between the first signal pad and the second signal pad. The embedded capacitance between the first signal pad and the second signal pad is configured to carry a signal between the first layer and the second layer absent a signal via.

In another embodiment, a system includes a first signal pad and a second signal pad. The first signal pad is in a first layer of a printed circuit board, and the second signal pad is in a second layer of the printed circuit board. The second signal pad is positioned to form an embedded capacitance between the first signal pad and the second signal pad. The embedded capacitance between the first signal pad and the second signal pad is configured to carry a signal between the first layer and the second layer absent a signal via.

In yet another embodiment, a computer program product for designing a printing circuit board includes a computer readable storage medium having program instructions embodied therewith. The program instructions are executable by a processor to cause the processor to perform a method. The method includes positioning a first signal pad in a first layer of a printed circuit board and positioning a second signal pad in a second layer of the printed circuit board. The second signal pad is positioned to form an embedded capacitance between the first signal pad and the second signal pad. The embedded capacitance between the first signal pad and the second signal pad is configured to carry a signal between the first layer and the second layer absent a signal via.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE DRAWINGS

The subject matter which is regarded as the invention is particularly pointed out and distinctly claimed in the claims at the conclusion of the specification. The forgoing and other features, and advantages of the invention are apparent from the following detailed description taken in conjunction with the accompanying drawings in which:

FIG. 1 is a diagram of a printed circuit board (PCB), according to some embodiments of this disclosure;

FIG. 2A is a diagram of a conventional PCB;

FIG. 2B is diagram of a PCB improving upon the conventional PCB of FIG. 2A, according to some embodiments of this disclosure;

FIG. 3A is another diagram of a conventional PCB;

FIG. 3B is diagram of a PCB improving upon the conventional PCB of FIG. 3A, according to some embodiments of this disclosure;

FIG. 4 is a flow diagram of a method for producing or designing a PCB, according to some embodiments of this disclosure; and

FIG. 5 is a block diagram of a computer system for designing a PCB, according to some embodiments of this disclosure.

### DETAILED DESCRIPTION

According to some embodiments, pad-to-pad capacitance between two traces embedded in the layout of a printed circuit board (PCB) may be sufficient to transmit high-speed signals in alternating-current-coupled (AC-coupled) mode between two adjacent signal layers. In this case, no direct-current-coupled (DC-coupled) connection may be required between the signal layers, and this no vias need be used to connect the layers.

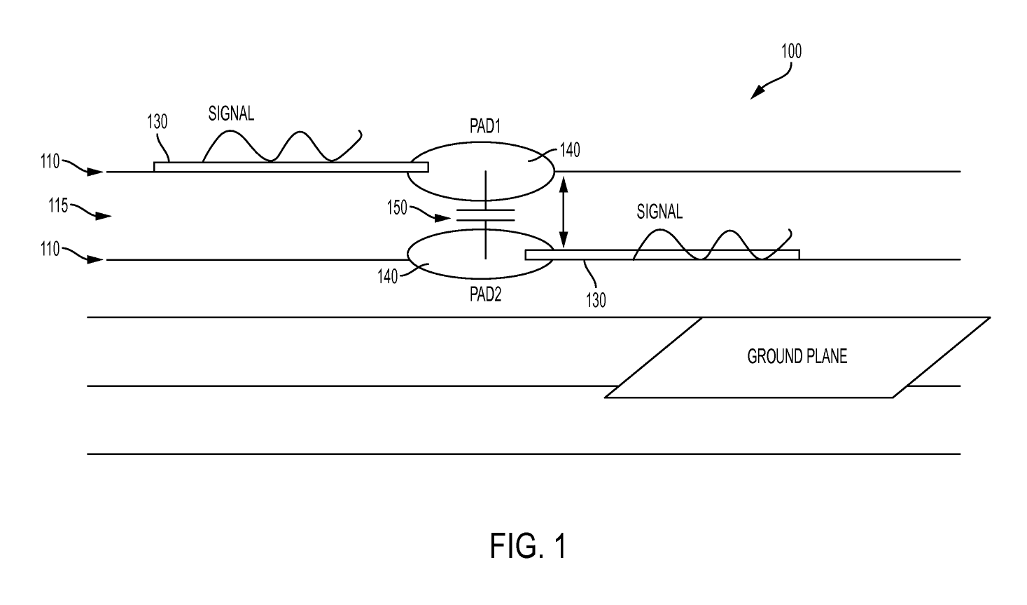

FIG. 1 is a diagram of a printed circuit board (PCB), according to some embodiments of this disclosure. As shown, the PCB 100 may include two or more layers 110, which may be formed of copper, for example. Dielectric planes 115, or dielectric layers, may separate these layers 110 from one another. The PCB 100 may include one or more traces 130. A signal may be carried by the traces 130 and passed between layers 110 by way of signal pads 140, each of which may be exposed metal. In some embodiments, embedded capacitance 150 may form between a first signal pad 140a on a first layer 110a and a second signal pad 140b on a second layer 110b, where the first and second layers 110 are adjacent and thus have an intervening dielectric plane 115 but no intervening layers 110.

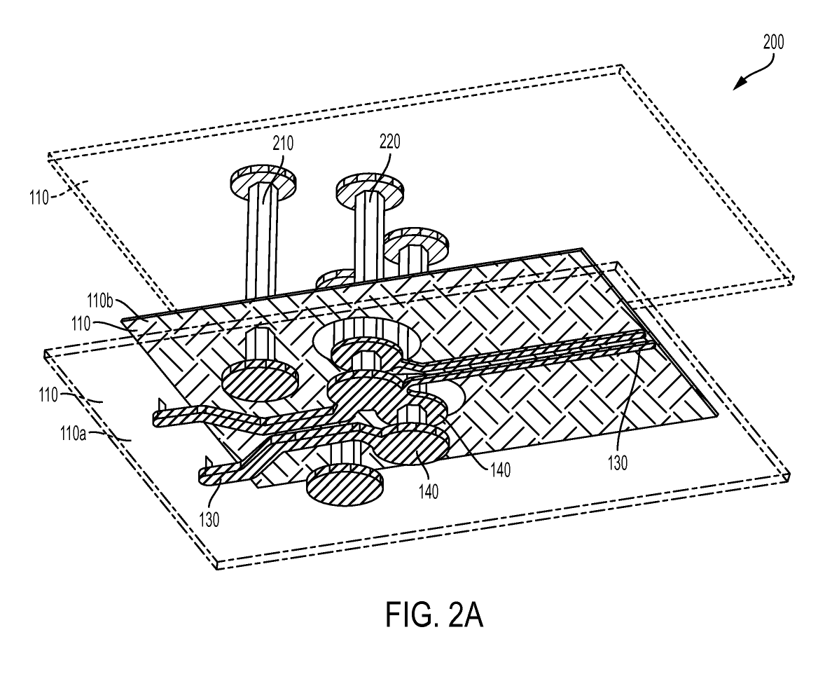

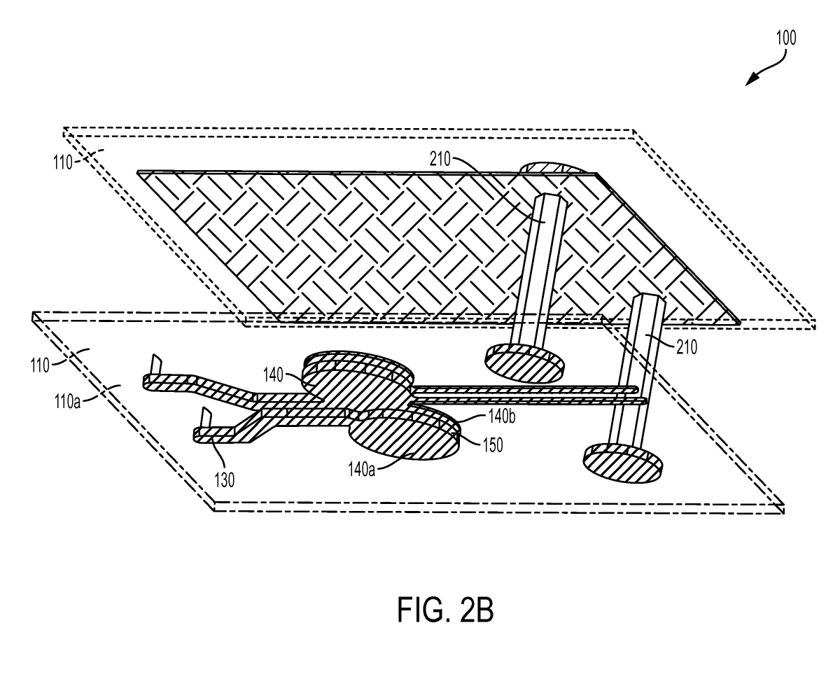

This arrangement of the PCB 100 may enable signal transition between adjacent layers 110 without the use of a signal via 220 (see FIG. 2A) for transmitting that signal between layers 110. In some embodiments, the perpendicular distance between the adjacent first and second layers 110a and 110b may be small enough that the embedded capacitance 150 between the first and second signal pads 140a and 140b is dominant (e.g., at least approximately 5 times larger) compared to the signal-to-ground capacitance. Thus, the embedded capacitance 150 between the first and second signal pads 140a and 140b may be sufficient to guarantee a low impedance (e.g., in the order of the milli-ohms for frequencies larger than approximately 15 GHz) between the first layer 110a and the second layer 110b, thus enabling the signal to propagate from the first signal pad 140a to the second signal pad 140b in alternating-current-coupled (AC-coupled) mode. In other words, the pad-to-pad capacitance (i.e., the embedded capacitance 150) between the first and second signal pads 140a and 140b may be sufficient to transmit high-speed signals in AC-coupled mode between two adjacent layers 100.

Additionally, in some embodiments, the embedded capacitance 150 created between the first and second signal pads 140a and 140b may behave as a direct current (DC) block capacitor, eliminating the need for a surface mounted component for DC blocking.

FIG. 2A is diagram of a conventional PCB 200, upon which embodiments of this disclosure may improve. In this example, the layers 110 include two surface layers 110 and an inner layer 110, but it will be understood that fewer or more layers 110 may be included. The conventional PCB 200 may further include one or more ground vias 210, which may be metal stubs passing between layers 110 for the purpose of grounding. The conventional PCB 200 may include one or more traces 130. The traces 130 may extend to and from one or more signal pads 140. Additionally, in contrast to the PCB 100 of FIG. 1, one or more signal vias 220 (i.e., metal stubs for passing a signal between layers 110) connect two adjacent layers 110 in the conventional PCB 200.

FIG. 2B is a diagram of a PCB 100 that improves upon the conventional PCB of FIG. 2A, according to some embodiments of this disclosure. As shown, in some embodiments, the PCB 100 may avoid use of the signal vias 220. Instead, a first signal pad 140a on a first layer 110a and a second signal pad 140b on a second layer 110b may be sized and positioned (e.g., aligned with each other) to create embedded capacitance 150 between the first signal pad 140a and second signal pad 140b. As discussed above, the first and second layers 110a and 110b that include, respectively, the first and second signal pads 140a and 140b may be adjacent layers 110. Further, in some embodiments, as shown, one of such layers 110 may be a surface layer 110, while the other is an inner layer 110.

Signals may be carried across the signal pads 140, thus removing the need for the signal vias 220. The use of larger signal pads 140 may increase the embedded capacitance 150 as compared to smaller signal pads 140, and thus, as compared to the conventional PCB 200, a PCB 100 according to some embodiments may use larger signal pads 140. Additionally, as illustrated in comparing FIG. 2A with FIG. 2B, the ground vias 210 may be moved in the PCB 100 to leave enough space for the larger signal pads 140 in the geometry without signal vias 220.

According to some embodiments, the PCB 100 may still include one or more signal vias 220 but, in that case, may include the embedded capacitance 150 discussed above in place of one or more additional signal vias 220. In other words, the technique described herein of replacing signal vias 220 with embedded capacitance 150 between signal pads 140 need not be used to remove every signal via 220 in a conventional PCB 200.

Various benefits may result from removing signal vias 220. For example, in some embodiments, the PCB 100 may have no stub resonances and thus reduced signal losses, as compared to a conventional PCB 200 with signal vias 220. Via transition resonances due to reflections of card edges may be minimized or reduced, as compared to conventional PCBs 200. Cross-talk between high-speed signals may be minimized or reduced, because the vertical coupling length may be significantly reduced. Further, routing in areas of dense signaling, such as in the escape region under a single-chip microcomputer (SCM), a multi-chip module (MCM) module, or a large chip, may be simplified by keeping the signals on the layers 110 closer to the integrated circuit package (i.e., the substrate supporting the PCB 100) without the need for signal vias 220, thus maintaining a good signal integrity.

In some embodiments, a thin dielectric plane 115 (e.g., approximately 1.5 millimeters) may be used between the first and second layers 110a and 110b. A thinner dielectric plane 115 may lead to a larger embedded capacitance 150. For that dielectric plane 115, a material with a high dielectric constant (e.g., greater than 10) material may be used to obtain low impedance transition. Further, material with a high dielectric constant may be concentrated around the signal pads 140 to avoid unwanted impedance changes in the traces 130. In other words, in the dielectric plane 115 separating the first and second layers 110a and 110b, a material with a higher dielectric constant may be used in the region aligned with the signal pads 140 having the embedded capacitance 150, as compared to other regions of the dielectric plane 115. For the dielectric plane 115 outside the embedded capacitance region, traditional low-loss materials may be used.

Additionally, in some embodiments, antipads of close reference layers 110 may be large enough for low or minimal signal-to-reference coupling. The reference layers 110 may be inner layers 110 that are used as references, such as a ground layer 110, and the antipads may be voids created to avoid a short circuit between a ground via 220 and the ground layer 110. In some embodiments, the reference layers 110 may be far away (e.g., more than 100 millimeters) from the signal pads 140 with embedded capacitance 150; otherwise, a portion of the signal could travel through the reference layers 110 instead of following the trace 130 and being carried across the embedded capacitance 150.

Three-dimensional simulations of using a PCB 100, according to some embodiments, have been performed. In those simulations, high-speed signals above 11 GHz propagated with a much-improved attenuation, as compared to a conventional PCB 200. However, modifying the material of the PCB 100 to achieve a higher dielectric constant increased the lower frequency insertion losses for frequencies less than 11 GHz. It will be understood, however, that some embodiments of the PCB 100 may operate effectively for signals below this frequency.

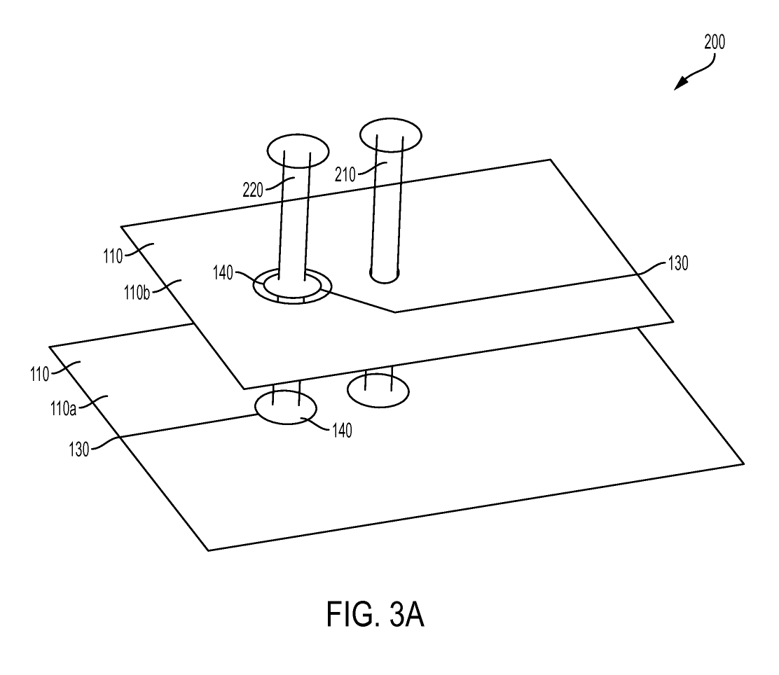

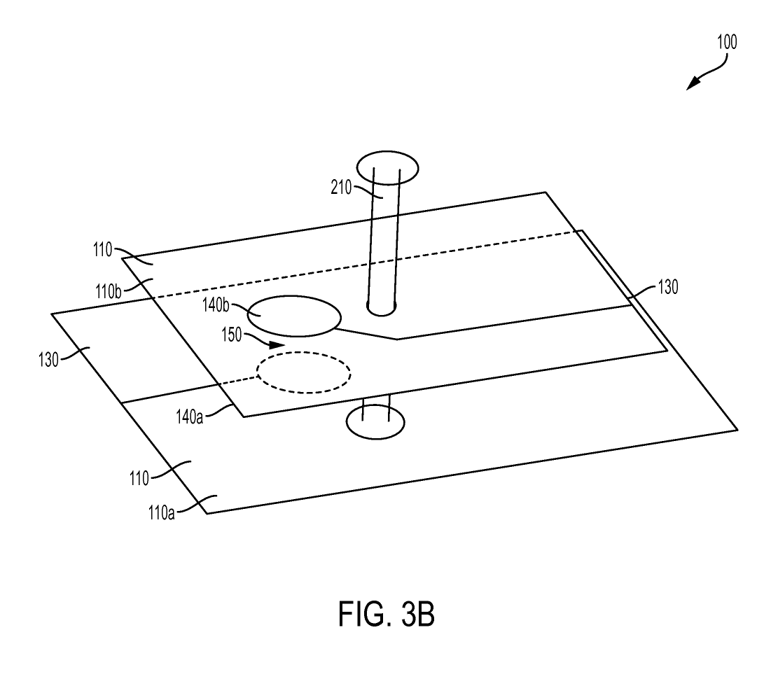

FIG. 3A is another diagram of a conventional PCB 200. In this example, one of the surface layers 110 has been eliminated from the figure to enable an improved view of the components. It will be understood that a surface layer 110 may be positioned adjacent to the illustrated inner layer 110b, as shown in FIG. 2A. In contrast to FIG. 2A, however, which depicts a conventional PCB 200 with a differential pair of signal vias 220 (i.e., two signal vias 220 in parallel), the conventional PCB 200 of FIG. 3A is used for single-ended patterns, in which signals are carried between layers 110 by a single signal via 220.

FIG. 3B is a diagram of a PCB 100 that improves upon the conventional PCB 200 of FIG. 3A, according to some embodiments of this disclosure. In this figure, the dashed lines depict components that are not visible from the shown perspective, due to being hidden by the inner layer 110b. As shown, the signal via 220 may be eliminated in this PCB 100, and embedded capacitance 150 may be formed between signal pads 140 for transmitting signals.

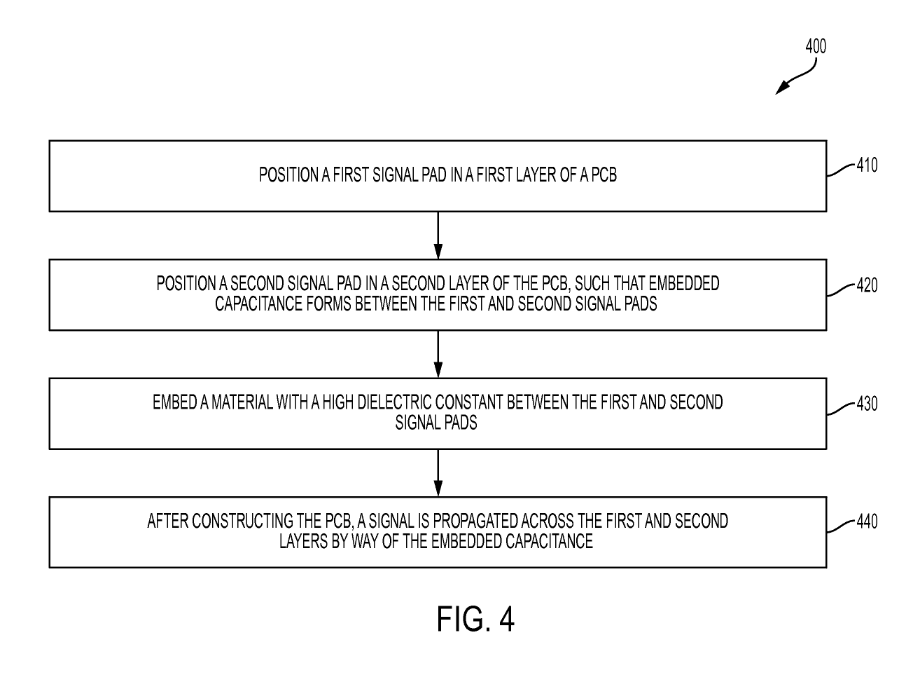

FIG. 4 is a flow diagram of a method 400 for constructing or designing a PCB 100, according to some embodiments of this disclosure. As shown, at block 410, a first signal pad 140a may be positioned in a first layer 110a of a PCB 100. At block 420, a second signal pad 140b may be positioned in a second layer 110b of the PCB 100. The position and size of the first and second signal pads 140a and 140b may be such that embedded capacitance 150 forms between the first signal pad 140a and the second signal pad 140b. At block 430, a material with a high dielectric constant may be embedded between the first and second signal pads 140a and 140b, without expanding into the nearby area, so as to increase the embedded capacitance 150 without impacting the impedance of the trace 130. At block 440, after the PCB 100 is constructed, a signal may be propagated across the embedded capacitance 150, and thus between the first and second layers 110a and 110b of the PCB 100, in AC-coupled mode.

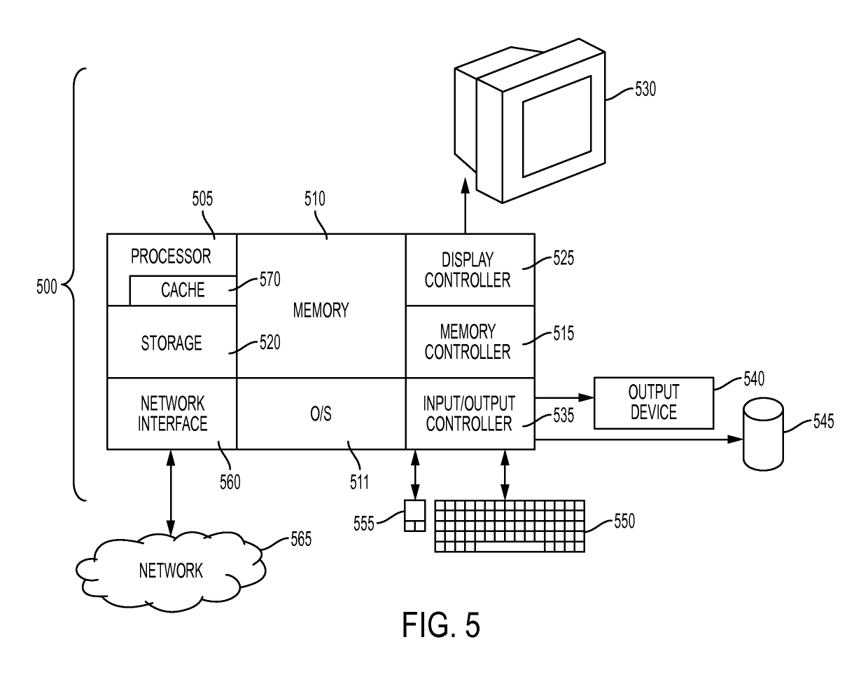

FIG. 5 illustrates a block diagram of a computer system 500 for use in designing a PCB 100 according to some embodiments. Systems and methods for designing the PCB 100 may be implemented in hardware, software (e.g., firmware), or a combination thereof. In some embodiments, the methods may be implemented, at least in part, in hardware and may be part of the microprocessor of a special or general-purpose computer system 500, such as a personal computer, workstation, minicomputer, or mainframe computer.

In some embodiments, as shown in FIG. 5, the computer system 500 includes a processor 505, memory 510 coupled to a memory controller 515, and one or more input devices 545 and/or output devices 540, such as peripherals, that are communicatively coupled via a local I/O controller 535. These devices 540 and 545 may include, for example, a printer, a scanner, a microphone, and the like. Input devices such as a conventional keyboard 550 and mouse 555 may be coupled to the I/O controller 535. The I/O controller 535 may be, for example, one or more buses or other wired or wireless connections, as are known in the art. The I/O controller 535 may have additional elements, which are omitted for simplicity, such as controllers, buffers (caches), drivers, repeaters, and receivers, to enable communications.

The I/O devices 540, 545 may further include devices that communicate both inputs and outputs, for instance disk and tape storage, a network interface card (NIC) or modulator/demodulator (for accessing other files, devices, systems, or a network), a radio frequency (RF) or other transceiver, a telephonic interface, a bridge, a router, and the like.

The processor 505 is a hardware device for executing hardware instructions or software, particularly those stored in memory 510. The processor 505 may be a custom made or commercially available processor, a central processing unit (CPU), an auxiliary processor among several processors associated with the computer system 500, a semiconductor based microprocessor (in the form of a microchip or chip set), a macroprocessor, or other device for executing instructions. The processor 505 includes a cache 570, which may include, but is not limited to, an instruction cache to speed up executable instruction fetch, a data cache to speed up data fetch and store, and a translation lookaside buffer (TLB) used to speed up virtual-to-physical address translation for both executable instructions and data. The cache 570 may be organized as a hierarchy of more cache levels (L1, L2, etc.).

The memory 510 may include one or combinations of volatile memory elements (e.g., random access memory, RAM, such as DRAM, SRAM, SDRAM, etc.) and nonvolatile memory elements (e.g., ROM, erasable programmable read only memory (EPROM), electronically erasable programmable read only memory (EEPROM), programmable read only memory (PROM), tape, compact disc read only memory (CD-ROM), disk, diskette, cartridge, cassette or the like, etc.). Moreover, the memory 510 may incorporate electronic, magnetic, optical, or other types of storage media. Note that the memory 510 may have a distributed architecture, where various components are situated remote from one another but may be accessed by the processor 505.

The instructions in memory 510 may include one or more separate programs, each of which comprises an ordered listing of executable instructions for implementing logical functions. In the example of FIG. 5, the instructions in the memory 510 include a suitable operating system (OS) 511. The operating system 511 essentially may control the execution of other computer programs and provides scheduling, input-output control, file and data management, memory management, and communication control and related services.

Additional data, including, for example, instructions for the processor 505 or other retrievable information, may be stored in storage 520, which may be a storage device such as a hard disk drive or solid state drive. The stored instructions in memory 510 or in storage 520 may include those enabling the processor to execute one or more aspects of the systems and methods for designing a PCB 100 of this disclosure.

The computer system 500 may further include a display controller 525 coupled to a display 530. In some embodiments, the computer system 500 may further include a network interface 560 for coupling to a network 565. The network 565 may be an IP-based network for communication between the computer system 500 and an external server, client and the like via a broadband connection. The network 565 transmits and receives data between the computer system 500 and external systems. In some embodiments, the network 565 may be a managed IP network administered by a service provider. The network 565 may be implemented in a wireless fashion, e.g., using wireless protocols and technologies, such as WiFi, WiMax, etc. The network 565 may also be a packet-switched network such as a local area network, wide area network, metropolitan area network, the Internet, or other similar type of network environment. The network 565 may be a fixed wireless network, a wireless local area network (LAN), a wireless wide area network (WAN) a personal area network (PAN), a virtual private network (VPN), intranet or other suitable network system and may include equipment for receiving and transmitting signals.

Systems and methods for designing a PCB 100 according to this disclosure may be embodied, in whole or in part, in computer program products or in computer systems 500, such as that illustrated in FIG. 5.

Technical effects and benefits of some embodiments of this disclosure include the ability to form a PCB 100 that avoids the use of some or all signal vias 220. As a result, discontinuities often created by signal vias 220 can be avoided, while signals can still be carried across layers 110 of the PCB, particularly at high frequencies.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiments were chosen and described in order to best explain the principles of the invention and the practical application, and to enable others of ordinary skill in the art to understand the invention for various embodiments with various modifications as are suited to the particular use contemplated.

The present invention may be a system, a method, and/or a computer program product. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Java, Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method comprising:
positioning a first signal pad in a first layer of a printed circuit board; and
positioning a second signal pad in a second layer of the printed circuit board, the second signal pad positioned to form an embedded capacitance between the first signal pad and the second signal pad;
the embedded capacitance between the first signal pad and the second signal pad configured to carry a signal between the first layer and the second layer absent a signal via.

2. The method of claim 1, wherein the embedded capacitance between the first signal pad and the second signal pad is configured to provide a low enough impedance between the first layer and the second layer to propagate the signal from the first signal pad to the second signal pad in alternating-current-coupled mode.

3. The method of claim 2, wherein the embedded capacitance is configured to behave as a direct current block capacitor.

4. The method of claim 1, further comprising:
layering a dielectric plane between the first layer and the second layer of the printed circuit board;
wherein a region of the dielectric plane aligned with the first signal pad and the second signal pad has a dielectric constant higher than a dielectric constant in another region of the dielectric plane.

5. The method of claim 1, wherein reducing a thickness of a dielectric layer between the first layer and the second layer of the printed circuit board increases the embedded capacitance between the first signal pad and the second signal pad.

6. The method of claim 1, wherein increasing a size of the first signal pad and the second signal pad increases the embedded capacitance between the first signal pad and the second signal pad.

7. The method of claim 1, wherein a distance between the first layer and the second layer is small enough that the embedded capacitance between the first signal pad and the second signal pad is greater than a signal-to-ground capacitance of the printed circuit board.
